(19) United States
(12) Patent Application Publication
(10) Pub. No.: US 2022/0336769 A1
(43) Pub. Date: Oct. 20, 2022

(54) DISPLAY-SCREEN PIXEL

(71) Applicant: ISORG, Limoges CEDEX 3 (FR)

(72) Inventors: Benjamin BOUTHINON, GRENOBLE (FR); Jeremy LOUIS, GRENOBLE (FR); Emeline SARACCO, GRENOBLE (FR)

(21) Appl. No.: 17/639,551

(22) PCT Filed: Aug. 31, 2020
(86) PCT No.: PCT/EP2020/074192

§ 371 Date: Mar. 1, 2022

(30) Foreign Application Priority Data
Sep. 2, 2019 (FR) FR1909617

(51) Int. Cl. H01L 51/50; H01L 51/56; H01L 27/32; H01L 51/52

(52) U.S. Cl. CPC H01L 51/5088; H01L 51/56; H01L 27/3227; H01L 51/5284

(57) ABSTRACT

A pixel includes at least one organic light-emitting component including a first hole injection layer; and at least one organic photodetector, including a second hole injection layer. The first and second hole injection layers are made of a same material.

This patent application claims the priority of French patent application 19/09617 which will be considered as an integral part of this description.

### FIELD

The present disclosure generally concerns optoelectronic devices and, more particularly, devices comprising a display screen and an image sensor.

### BACKGROUND

Many current electronic devices, such as cell phones, touch pads, laptop computers, smart watches, are equipped both with a display screen, often a touch screen, and with a fingerprint sensor. The fingerprint sensor is most of the time arranged outside of an area occupied by the display screen. Such a fingerprint sensor is usually made in the form of an image sensor.

In the case, for example, of smart phones, the fingerprint sensor is generally integrated to Home button located at the front surface of the device. Such an architecture has as a main disadvantage that it limits the space available for other elements of the telephone. In particular, this results in restricting the surface area allocated, at the front surface, to the telephone display screen. This generally results in an increase of the external dimensions of the device, or in a decrease of the area occupied by the display screen.

Telephones having their fingerprint sensor located on the back side of the device are further known. This thus enables to free space at the front surface to the benefit, for example, of the display screen. Such an architecture however turns out adversely affecting the general user-friendliness of the telephone. The fingerprint sensor is then indeed located in an area difficult to access by the user, in particular when the device is laid on its back side.

### SUMMARY

There is a need to improve electronic devices integrating an image sensor and a display screen.

An embodiment overcomes all or part of the disadvantages of electronic devices integrating a known image sensor and display screen.

An embodiment provides a pixel comprising:
at least one organic light-emitting component, comprising a first hole injection layer; and
at least one organic photodetector, comprising a second hole injection layer,
wherein the first and second hole injection layers are made of a same material.

According to an embodiment:
the first hole injection layer is coated with a first active layer of the organic light-emitting component;
and the second hole injection layer coats a second active layer of the organic photodetector.

According to an embodiment, the first active layer and the second hole injection layer are coated with a same electrode.

According to an embodiment, the electrode forms an anode electrode of the organic photodetector and a cathode electrode of the organic light-emitting component.

According to an embodiment, the material of the first and second hole injection layers is a mixture of poly(3,4)-ethylenedioxythiophene and of polystyrene sodium sulfonate, PEDOT:PSS.

According to an embodiment, the first and second hole injection layers are electrically insulated from each other.

According to an embodiment, the first and second hole injection layers are perpendicular to a direction of light emission by the organic light-emitting component and to a direction of light reception by the organic photodetector.

According to an embodiment:
the organic light-emitting component further comprises an anode electrode; and
the organic photodetector further comprises a cathode electrode electrically insulated from the anode electrode of the organic light-emitting component.

An embodiment provides a method of manufacturing a pixel comprising:
at least one organic light-emitting component, comprising a first hole injection layer; and
at least one organic photodetector, comprising a second hole injection layer,
wherein the first and second hole injection layers are made of a same material.

According to an embodiment, the first hole injection layer and the second hole injection layer are formed during a same step.

According to an embodiment, the first hole injection layer and the second hole injection layer are formed from a same third layer.

An embodiment provides a method of manufacturing a pixel such as described.

An embodiment provides an optoelectronic device comprising an array of pixels such as described.

According to an embodiment, the electrode is connected to all the organic light-emitting components and to all the organic photodetectors of a same row of the array.

According to an embodiment, the device comprises, above the organic photodetectors, one or a plurality of elements capable of performing an angular selection of light rays reflected by a user's finger, these elements taking the form:
of a black layer provided with openings;
of lenses; or
of a black layer provided with openings having lenses aligned therewith.

### BRIEF DESCRIPTION OF THE DRAWINGS

The foregoing and other features and advantages of the present invention will be discussed in detail in the following non-limiting description of specific embodiments and implementation modes in connection with the accompanying drawings, in which:

FIG. 1 is an exploded partial simplified perspective view of an embodiment of an optoelectronic device;

FIG. 2 is a partial simplified cross-section view of a step of an implementation mode of a method of forming the optoelectronic device of FIG. 1;

FIG. 3 is a partial simplified cross-section view of another step of the implementation mode of the method of forming the optoelectronic device of FIG. 1;

FIG. 4 is a partial simplified cross-section view of still another step of the implementation mode of the method of forming the optoelectronic device of FIG. 1;

FIG. 5 is a partial simplified cross-section view of still another step of the implementation mode of the method of forming the optoelectronic device of FIG. 1;

FIG. 6 is a partial simplified cross-section view of still another step of the implementation mode of the method of forming the optoelectronic device of FIG. 1;

FIG. 7 is a partial simplified cross-section view of still another step of the implementation mode of the method of forming the optoelectronic device of FIG. 1;

FIG. 8 is a partial simplified cross-section view of still another step of the implementation mode of the method of forming the optoelectronic device of FIG. 1;

FIG. 9 is a partial simplified cross-section view of still another step of the implementation mode of the method of forming the optoelectronic device of FIG. 1;

FIG. 10 is a partial simplified cross-section view of still another step of the implementation mode of the method of forming the optoelectronic device of FIG. 1;

FIG. 11 is a partial simplified cross-section view of still another step of the implementation mode of the method of forming the optoelectronic device of FIG. 1;

FIG. 12 is a partial simplified cross-section view of a step of a variant of the implementation mode of the method of forming the optoelectronic device of FIG. 1;

FIG. 13 is a partial simplified cross-section view of another step of the variant of the implementation mode of the method of forming the optoelectronic device of FIG. 1;

FIG. 14 is a partial simplified cross-section view of still another step of the implementation mode of the method of forming the optoelectronic device of FIG. 1;

FIG. 15 is a partial simplified cross-section view of still another step of the implementation mode of the method of forming the optoelectronic device of FIG. 1;

FIG. 16 is a partial simplified cross-section view of still another step of the implementation mode of the method of forming the optoelectronic device of FIG. 1;

FIG. 17 is a partial simplified cross-section view of still another step of the implementation mode of the method of forming the optoelectronic device of FIG. 1; and

FIG. 18 is a partial simplified cross-section view of another embodiment of an optoelectronic device.

### DESCRIPTION OF THE EMBODIMENTS

Like features have been designated by like references in the various figures. In particular, the structural and/or functional elements common to the different embodiments and implementation modes may be designated with the same reference numerals and may have identical structural, dimensional, and material properties.

For clarity, only those steps and elements which are useful to the understanding of the described embodiments and implementation modes have been shown and will be detailed. In particular, the operation of the display screen and of the image sensor has not been detailed, the described embodiments being compatible with usual display screens. Further, the other components of the electronic device integrating a display screen and an image sensor have not been detailed either, the described embodiments being compatible with the other usual components of electronic devices comprising a display screen.

Unless specified otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., unless otherwise specified, it is referred to the orientation of the drawings.

Unless specified otherwise, the expressions “around”, “approximately”, “substantially” and “in the order of” signify within 10%, and preferably within 5%.

In the following description, unless specified otherwise, it is considered that the terms “insulating” and “conductive” respectively mean “electrically insulating” and “electrically conductive”.

An image pixel corresponds to a unit element of the image displayed by the display screen. When the display screen is a color image display screen, it generally comprises, for the display of each image pixel, at least three emission and/or light intensity regulation components, which each emit light radiation substantially in a single color (for example, red, green, or blue). The superposition of the radiations emitted by the components provides the observer with the colored sensation corresponding to the pixel of the displayed image. When the display screen is a monochrome image display screen, it generally comprises a single light source for the display of each pixel of the image.

The expression active region of an optoelectronic component, particularly of a light-emitting component or of a photodetector, designates the region from which most of the electromagnetic radiation supplied by the optoelectronic component is emitted or the region from which most of the electromagnetic radiation received by the optoelectronic component is captured. In the following description, an optoelectronic component is called organic when the active region of the optoelectronic component is mainly, preferably totally, made of at least one organic material or of a mixture of organic materials.

Devices integrating an optical sensor or an ultrasound sensor behind a display screen comprising organic light-emitting diodes are known. A disadvantage of such devices lies in the fact that the integration of the sensor behind the screen causes an increase in the total thickness of the device or a decrease in the thickness available for a battery equipping the device. The larger the surface area of the sensor to be integrated, the smaller the thickness available for the battery, and thus its capacitance, thus resulting in a decrease in the autonomy of the device. A solution to overcome this disadvantage comprises integrating the sensor and the display screen on a same substrate, in other words in a same device.

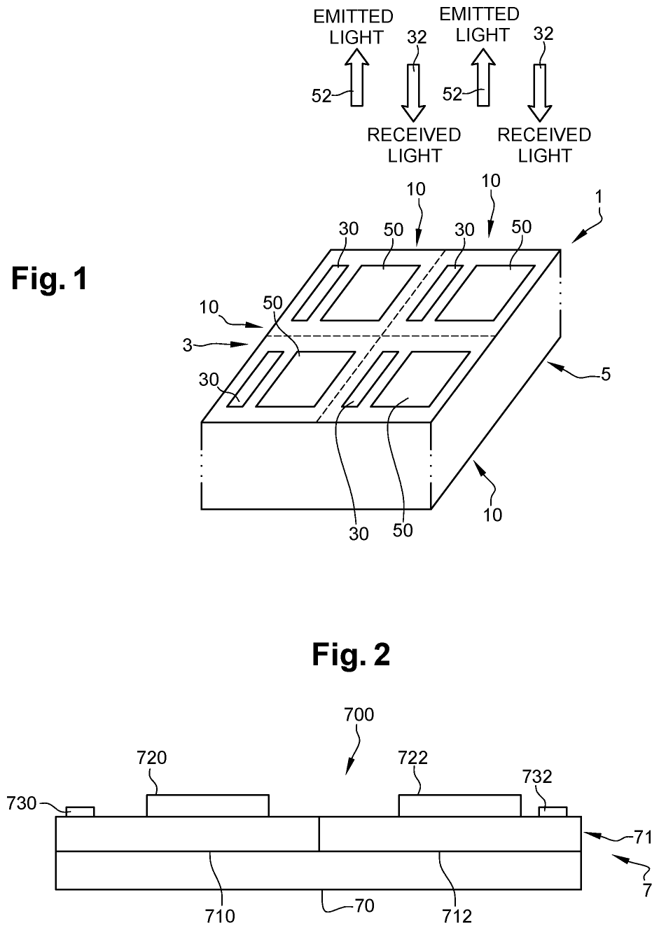

FIG. 1 is a partial simplified exploded perspective view of an embodiment of an optoelectronic device 1.

According to this embodiment, optoelectronic device 1, very schematically shown in FIG. 1, comprises an image sensor 3 and a display screen 5. Image sensor 3 comprises an array of organic photodetectors 30. Organic photodetectors 30 may correspond to organic photodiodes (OPD) or to organic photoresistors. Similarly, display screen 5 comprises an array of organic light-emitting components 50. Organic light-emitting components 50 are for example organic light-emitting diodes (OLED). Device 1 may thus be indifferently considered either as a display screen 5, having an image sensor 3 integrated thereto, or as an image sensor 3, having a display screen 5 integrated thereto.

Optoelectronic device 1 is formed of a pixel array 10, each of pixels 10 comprising, still according to this embodiment, a single organic photodetector 30 and a single organic light-emitting component 50. FIG. 1 shows pixels having a substantially square shape, each pixel 10 comprising an organic photodetector 30 and a light-emitting component 50, both of rectangular shape. It should however be understood that, in practice, pixels 10, organic photodetectors 30, and light-emitting components 50 may have other shapes than those illustrated in FIG. 1. Light-emitting components 50 may particularly occupy a greater surface area than photodetectors 30, as shown in FIG. 1, to favor a light emission by display screen 5. All the pixels 10 of optoelectronic device 1 preferably have substantially identical dimensions, to within manufacturing dispersions.

Further, the light-emitting components 50 and the photodetectors 30 of optoelectronic device 1 are separated from one another, at least at their surface, by areas made of an insulating material. Such areas particularly aim at allowing an individual addressing of light-emitting components 50 and of photodetectors 30.

FIG. 1 shows, with first arrows 32 (RECEIVED LIGHT), a direction of light reception of the organic photodetectors 30 of image sensor 3. Similarly, second arrows 52 (EMITTED LIGHT) show a light emission direction by the organic light-emitting components 50 of display screen 5.

According to this embodiment, the light emission and reception are performed in opposite directions, respectively towards and from the top, in FIG. 1. The light emission and reception occur on the side of the surface having photodetectors 30 and light-emitting components 50 located therein, called upper surface of optoelectronic device 1. Photodetectors 30 and light-emitting components 50 are coplanar. Photodetectors 30 and light-emitting components 50 are, in FIG. 1, arranged side by side in a same plane perpendicular to a light emission and light reception direction.

In a case where optoelectronic device 1 equips a cell phone, the light emission and reception are respectively performed toward and from the outside of the phone. In particular, if optoelectronic device 1 forms a main display screen located at the front surface of the phone, optoelectronic device 1 is then oriented so that the light emission occurs towards the outside of the phone and the light reception is performed from the outside of the phone.

According to another embodiment, not shown, the light emission and reception are performed on the side opposite to photodetectors 30 and to light-emitting components 50, that is, towards and from a lower surface of optoelectronic device 1 (towards and from the bottom, in FIG. 1).

For clarity, only four pixels 10 of optoelectronic device 1 have been shown in FIG. 1. However, optoelectronic device 1 may in practice comprise many more pixels 10, for example, several millions, or even several tens of millions of pixels 10. Optoelectronic device 1 preferably has a resolution greater than or equal to 500 ppi (pixels per inch). Photodetectors 30 and light-emitting components 50 may have lateral dimensions in the order of from 10 μm to 50 μm.

FIGS. 2 to 17 hereafter illustrate successive steps of an implementation mode of an embodiment of the optoelectronic device 1 of FIG. 1. For simplification, what is discussed hereafter in relation with FIGS. 2 to 17 illustrates the forming of a single pixel 10 of optoelectronic device 1. However, it will be within the abilities of those skilled in the art to extend this method to the forming of an optoelectronic device similar to device 1 and comprising any number of pixels 10 based on the following indications.

FIG. 2 is a partial simplified cross-section view of a step of an implementation mode of an embodiment of the optoelectronic device 1 of FIG. 1.

According to this implementation mode, it is started by providing a support 7, this support comprising, from bottom to top in FIG. 2:
a substrate 70;
a stack 71 comprising a first area 710 and a second area 712, coplanar to each other, within which are respectively formed thin-film transistors (TFT), not shown in FIG. 2;
a first electrode 720, located vertically in line with the first area 710 of stack 71 and a second electrode 722, located vertically in line with the second area 712 of stack 71; and
a first connection pad 730 located vertically in line with the first area 710 of stack 71 and a second connection pad 732 located vertically in line with the second area 712 of stack 71.

The thin-film transistors of the first area 710 and of the second area 712 of stack 71 may in practice be formed according to identical or different technologies. According to an embodiment:
the thin-film transistors of the first area 710, intended to address the pixels of image sensor 3, are made of indium, gallium, and zinc oxide (IGZO) or of amorphous silicon (aSi); and
the thin-film transistors of the second area 712, intended to address the pixels of display screen 5, are made of low-temperature polycrystalline silicon (LIPS).

First pad 730 and second pad 732 are intended to bias an upper electrode (not shown in FIG. 2) common to all the pixels of image sensor 3 and of display screen 5. According to an embodiment, not shown, first pad 730 and second pad 732 are placed in a single location, which location may be located outside of the pixel array.

The first and second electrodes 720, 722 partially cover an upper surface 700 of support 7 (at the top, in FIG. 2). In the case where optoelectronic device 1 is intended to equip a cell phone, upper surface 700 is oriented towards the outside of the phone, the light emission and reception then being respectively performed through upper surface 700.

First electrode 720 is coupled, preferably connected, to a first thin-film transistor (not shown) located in the first area 710 of stack 71. Similarly, second electrode 722 is coupled, preferably connected, to a second thin-film transistor (not shown) located in the second layer 712 of stack 71. Each electrode 720, 722 is also designated by the term “contacting element”. The first electrode 720 is intended to form a cathode electrode 720 of photodetector 30 while the second electrode 722 is intended to form an anode electrode 722 of light-emitting component 50.

During this same step, support 7 is cleaned to remove possible impurities present at upper surface 700, on electrodes 720, 722, and on pads 730, 732. The cleaning is for example performed by plasma treatment. The cleaning thus provides a satisfactory cleanness of support 7, of electrodes 720, 722, and of pads 730, 732 before a series of successive depositions, detailed in relation with the following drawings, are performed.

The substrate 70 of support 7 may be a rigid or flexible substrate. Substrate 70 may further be formed of a monolayer or multilayer structure, that is, of a structure formed of a vertical stack of at least two layers. In the case where substrate 70 is rigid, substrate 70 is for example made of silicon (doped or not), of germanium (doped or not), or of glass.

According to a preferred implementation mode, substrate 70 is a flexible film. Substrate 70 then is a film of PEN (polyethylene naphthalate), PET (polyethylene terephthalate), PI (polyimide), TAC (cellulose triacetate), COP (cycloolefin copolymer), or PEEK (polyetheretherketone). The thickness of substrate 70 may be in the range from 20 μm to 2,000 μm.

According to another embodiment, substrate 70 may have a thickness from 10 μm to 300 μm, preferably in the range from 75 μm to 250 μm, particularly in the order of 150 μm, and may have a flexible behavior, that is, substrate 70 may, under the action of an external force, deform, and particularly bend, without breaking or tearing. Substrate may comprise a multilayer structure formed of a plurality of films, for example, a PET film having a thickness of approximately 100 μm laminated, by means of an adhesive, on a polyimide film having a thickness of approximately 20 μm.

Substrate 70 may comprise at least one substantially oxygen- and moisture-tight layer, to protect the organic layers of device 1. This may be one or a plurality of layers deposited by an atomic layer deposition (ALD) method, for example, an Al₂O₃ layer. The deposition of protection of the organic layers of device 1 may also be performed by physical vapor deposition (PVD) or by plasma-enhanced chemical vapor deposition (PECVD), in particular in the case of a silicon nitride (SiN) or silicon oxide (SiO₂) deposition.

As a variant, the deposit for protecting the organic layers of device 1 is formed of a multilayer structure comprising an alternation of one or a plurality of inorganic layers and of one or a plurality of organic layers. According to this variant:
the inorganic layers are based on SiN and/or on SiO₂, the inorganic layers preferably being deposited by PECVD; and
the organic layers are based on a dielectric material, the organic layers being preferably deposited by inkjet.

According to an embodiment, the materials forming electrodes 720, 722 and connection pads 730, 732 are selected from the group comprising:
a metal or a metallic alloy, for example, silver (Ag), aluminum (Al), lead (Pb), palladium (Pd), gold (Au), copper (Cu), nickel (Ni), tungsten (W), molybdenum (Mo), titanium (Ti), chromium (Cr), titanium nitride (TiN), or an alloy of magnesium and silver (MgAg);
a transparent conductive oxide (TCO), particularly indium tin oxide (ITO), aluminum zinc oxide (AZO), gallium zinc oxide (GZO), an ITO/Ag/ITO multilayer structure, an ITO/Mo/ITO multilayer structure, a AZO/Ag/AZO multilayer structure, or a ZnO/Ag/ZnO multilayer structure;
carbon, silver, and/or copper nanowires;
graphene; and
a mixture of at least two of these materials.

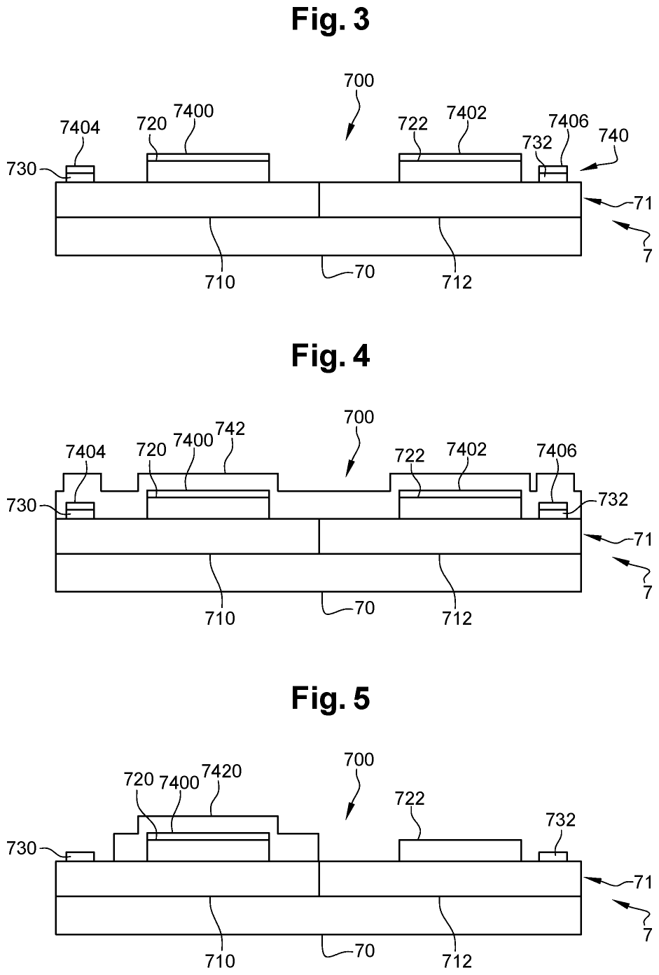

In the rest of the disclosure, the implementation mode of the method described in relation with FIGS. 3 to 17 exclusively comprises performing operations above the upper surface 700 of support 7. The support 7 of FIGS. 3 to 17 thus is preferably identical to the support 7 such as discussed in relation with FIG. 2 all along the process. For simplification, support 7 will not be detailed again in the following drawings.

FIG. 3 is a partial simplified cross-section view of another step of the implementation mode of the method of forming the optoelectronic device 1 of FIG. 1, based on the structure such as described in relation with FIG. 2.

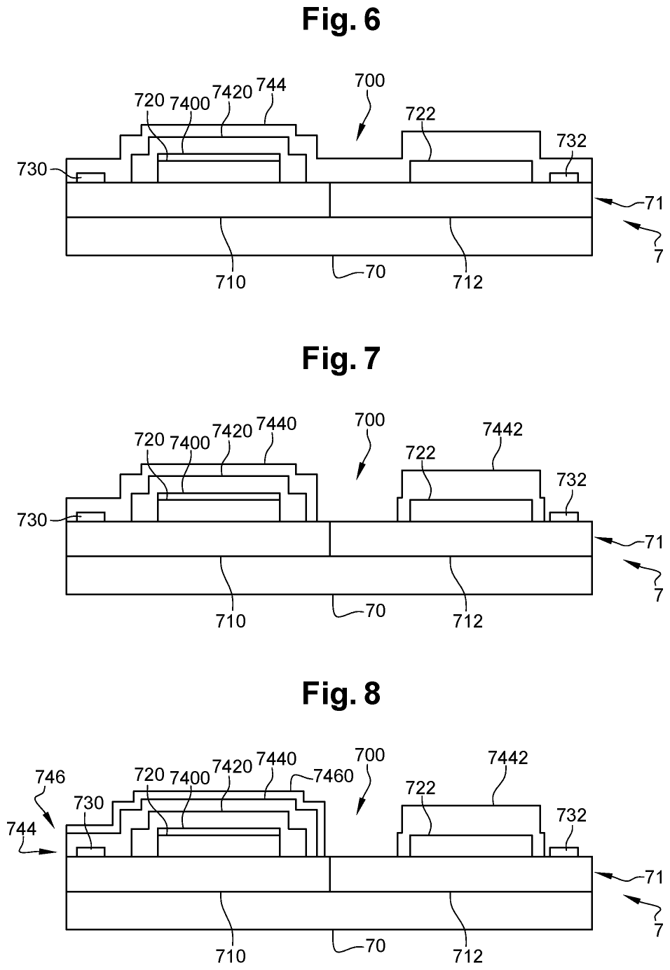

During this step, a deposition, on the upper surface side 700 of support 7, of a first layer 740, is performed. First layer 740 is preferably obtained by deposition of a material selectively (or preferentially) bonding to the surface of electrodes 720, 722 and of connection pads 730, 732, thus forming a self-assembled monolayer (SAM). This deposit thus only covers free upper surfaces of electrodes 720, 722 and of pads 730, 732. One thus more precisely forms, as illustrated in FIG. 6:
a first portion 7400 of first layer 740, covering first electrode 720;
a second portion 7402 of first layer 740, covering second electrode 722;
a third portion 7404 of first layer 740, covering first connection pad 730; and
a fourth portion 7406 of first layer 740, covering second connection pad 732.

As a variant, a continuous layer 740 made of a material having a sufficiently low lateral conductivity to prevent possible short-circuits from occurring between electrodes 720, 722 and pads 730, 732, is formed by a “full-plate” deposition.

According to the material forming electrodes 720, 722 and pads 730, 732, the method of forming portions 7400, 7402, 7404, and 7406 of first layer 740 may correspond to a so-called additive process, for example, by direct printing of a fluid or viscous composition comprising the material forming portions 7400, 7402, 7404, and 7406 of first layer 740 at the desired locations, for example, by inkjet printing, heliography, silk-screening, flexography, or nanoimprint.

According to the material forming electrodes 720, 722 and pads 730, 732, the method of forming portions 7400, 7402, 7404, and 7406 of first layer 740 may alternately correspond to a so-called subtractive process, where the material forming portions 7400, 7402, 7404, and 7406 of first layer 740 is deposited over the entire structure (“full-plate” deposition), and where non-used portions are then removed, for example, by photolithography, laser ablation, or by a lift-off method.

In the case of a deposition over the entire structure and according to the material(s) used, first layer 740 may be deposited by liquid deposition. It may in particular be a method such as spin coating, spray coating, heliography, slot-die coating, blade coating, flexography, silk-screening, or dip coating. As a variant, first layer 740 may be deposited by cathode sputtering or by evaporation. According to the implemented deposition method, a step of drying the deposited material(s) may be provided.

First layer 740 is intended to form an electron injection layer (EIL) of the future photodetector 30. First layer 740 is preferably made of a material selected from the group comprising:
a polyethyleneimine (PEI) polymer, a polyethyleneimine ethoxylated (PEIE), propoxylated, and/or butoxylated polymer, or a polyeletrolyte, for example poly[9,9-bis(3′-(N,N-dimethylamino)propyl)-2,7-fluorene-alt-2,7-(9,9-dioctyfluorene)] (PFN), first layer 740 then having a thickness in the range from 1 nm to 20 nm;
a metal oxide, particularly a zinc oxide (ZnO), a titanium oxide (TiOₓ), or a zirconium oxide (ZrOₓ), first layer 740 then having a thickness in the range from 10 nm to 100 nm;
a carbonate, for example, cesium carbonate (CsCO₃), or a lithium quinolate, for example 8-hydroxyquinolinolato-lithium (Liq), first layer 740 then having a thickness in the range from 10 nm to 100 nm;
calcium, first layer 740 then having a thickness in the range from 10 nm to 100 nm;
lithium fluoride (LiF), first layer 740 then having a thickness in the range from 0.2 nm to 2 nm; and
barium (Ba), first layer 740 then having a thickness in the range from 1 nm to 30 nm.

First layer 740, and thus its portions 7400, 7402, 7404, and 7406, may have a monolayer or multilayer structure.

FIG. 4 is a partial simplified cross-section view of still another step of the implementation mode of the method of forming the optoelectronic device 1 of FIG. 1, from the structure such as described in relation with FIG. 3.

During this step, a non-selective deposition (full-plate deposition) of a second layer 742 is performed on the side of the upper surface 700 of support 7. Second layer 742 thus covers free areas of the upper surface 700 of support 7 as well as first portion 7400, second portion 7402, third portion 7404, and fourth portion 7406 of first layer 740.

According to the material(s) used, second layer 742 may be deposited by liquid deposition. It may in particular be a method such as spin coating, spray coating, heliography, slot-die coating, blade coating, flexography, silk-screening, or dip coating. As a variant, second layer 742 may be deposited by cathode sputtering or by evaporation. According to the implemented deposition method, a step of drying the deposited material(s) may be provided.

Second layer 742 is intended to form an active layer of the future organic photodetector 30. Second layer 742 is preferably made of an organic semiconductor (OSC).

Second layer 742 may comprise small molecules, oligomers, or polymers. These may be organic or inorganic materials, particularly materials comprising quantum dots. Second layer 742 may comprise an ambipolar (non-doped) semiconductor material, or a mixture of an N-type semiconductor material and of a P-type semiconductor material, for example in the form of stacked layers or of an intimate mixture at a nanometer scale to form a bulk heterojunction. The thickness of second layer 742 may be in the range from 50 nm to 2 μm, preferably from 200 nm to 700 nm, for example, in the order of 300 nm.

Example of P-type semiconductor polymers capable of forming second layer 742 are poly(3-hexylthiophene) (P3HT), poly[N-9′-heptadecanyl-2,7-carbazole-alt-5,5-(4,7-di-2-thienyl-2′,1′,3′-benzothiadiazole)] (PCDTBT), poly[(4,8-bis-(2-ethylhexyloxy)-benzo[1,2-b;4,5-b′]dithiophene)-2,6-diyl-alt-(4-(2-ethylhexanoyl)-thieno[3,4-b]thiophene))-2,6-diyl] (PBDTTT-C), poly[2-methoxy-5-(2-ethyl-hexyloxy)-1,4-phenylene-vinylene] (MEH-PPV), or poly[2,6-(4,4-bis-(2-ethylhexyl)-4H-cyclopenta[2,1-b;3,4-b′]dithiophene)-alt-4,7(2,1,3-benzothiadiazole)] (PCPDTBT).

Examples of N-type semiconductor materials capable of forming second layer 742 are fullerenes, particularly C60, [6,6]-phenyl-C₆₁-methyl butanoate ([60]PCBM), [6,6]-phenyl-C₇₁-methyl butanoate ([70]PCBM), perylene diimide, zinc oxide (ZnO), or nanocrystals enabling to form quantum dots.

According to a preferred embodiment, second layer 742 is made of a mixture of P3HT and of PCBM.

FIG. 5 is a partial simplified cross-section view of still another step of the implementation mode of the method of forming the optoelectronic device 1 of FIG. 1, from the structure such as described in relation with FIG. 4.

During this step, portions of second layer 742 are removed (FIG. 4) to only keep, as illustrated in FIG. 5, a portion 7420 of second layer 742. In FIG. 5, portion 7420 of second layer 742 particularly covers first portion 7400 of first layer 740. Portion 7420 of second layer 742 corresponds to an active layer 7420 of the future organic photodetector 30. In other words, active layer 7420 corresponds to a region from which most of the electromagnetic radiation received by organic photodetector 30 is captured.

According to an embodiment, portion 7420 of second layer 742 is obtained by etching, using an etch mask, which may be formed by steps of photolithography on a positive or negative resist layer deposited over the entire layer 742, or by the deposition of resin blocks directly at the desired locations on second layer 742, for example, by inkjet printing, heliography, silk-screening, flexography, or nanoimprint. The etching may be a reactive ion etching (RIE) or a chemical etching.

Portion 7420 of second layer 742 may alternately be obtained by a selective deposition, for example, by inkjet printing or nanoimprint, without using photolithography steps.

The removal of the etch mask may be obtained by any stripping method, for example, by dipping the structure comprising the etch mask into a chemical bath or by reactive ion etching.

FIG. 6 is a partial simplified cross-section view of still another step of the implementation mode of the method of forming the optoelectronic device 1 of FIG. 1, from the structure such as described in relation with FIG. 5.

During this step, a non-selective deposition (full plate deposition) of a third layer 744 is performed on the side of upper surface 700 of support 7. Third layer 744 thus covers free areas of upper surface 700 of support 7 as well as first connection pad 730, second connection pad 732, portion 7420 of second layer 742, and second electrode 722.

According to the material(s) used, third layer 744 may be deposited by liquid deposition. This may in particular be a method such as spin coating, spray coating, heliography, slot-die coating, blade coating, flexography, silk-screening, or dip coating. As a variant, third layer 744 may be deposited by cathode sputtering or by evaporation. According to the implemented deposition method, a step of drying the deposited material(s) may be provided.

Third layer 744 is intended to form an electron injection layer (EIL) of the future photodetector 30 and of the future organic light-emitting component 50. Third layer 744 is preferably made of a material selected from the group comprising:
bis[(1-naphthyl)-N-phenyl]benzidine (NPB), third layer 744 then having a thickness in the range from 10 nm to 100 nm;
a mixture of poly(3,4)-ethylenedioxythiophene and of sodium polystyrene sulfonate (PEDOT:PSS), third layer 744 then having a thickness in the range from 20 nm to 200 nm; and
a metal oxide, for example, a molybdenum oxide (MoO₃), a nickel oxide (NiO), a tungsten oxide (WO₃), or a vanadium oxide (V₂O₅), where the metal oxides may form a single layer or a bi-layer or tri-layer structure of metal oxide and of layers made of silver (Ag) or of another metal, third layer 744 then having a total thickness in the range from 5 nm to 50 nm.

FIG. 7 is a partial simplified cross-section view of still another step of the implementation mode of the method of forming the optoelectronic device 1 of FIG. 1, from the structure such as described in relation with FIG. 6.

During this step, portions of third layer 744 (FIG. 6) are removed to only keep, as illustrated in FIG. 7, a first portion 7440 and a second portion 7442 of third layer 744. In this case, first portion 7440 of third layer 744 and second portion 7442 of third layer 744 are made of a same material. First portion 7440 of third layer 744 covers portion 7420 of second layer 742 and first connection pad 730. Second portion 7442 of third layer 744 covers second electrode 722 but does not cover second pad 732. Second portion 7442 of third layer 744 is preferably not in contact with second pad 732.

First portion 7440 of third layer 744 corresponds to a hole injection layer 7440 of the future organic photodetector 30. Similarly, second portion 7442 of third layer 744 corresponds to a hole injection layer 7442 of the future organic light-emitting component 50. In the shown example, first portion 7440 of this layer 744 and second portion 7442 of third layer 744 are electrically insulated from each other.

Holes injection layers 7440 and 7442 are perpendicular to the direction of light emission 52 (FIG. 1) by organic light-emitting component 50 and to the direction of light reception 32 (FIG. 1) by organic photodetector 30.

According to an embodiment, portions 7440 and 7442 of third layer 744 are obtained by etching, using an etch mask that may be formed by steps of photolithography on a positive or negative resist layer deposited over the entire third layer 744, or by the deposition of resin blocks directly at the desired locations on third layer 744, for example, by inkjet printing, heliography, silk-screening, flexography, or nanoimprint. The etching may be a reactive ion etching or a chemical etching.

The removal of the etch mask may be obtained by any stripping method, for example, by dipping the structure comprising the etch mask into a chemical bath or by reactive ion etching.

The structure of FIG. 7 may alternately be obtained by selective deposition of the hole injection layer, that is, of third layer 744, without using photolithography steps.

FIG. 8 is a partial simplified cross-section view of still another step of the implementation mode of the method of forming the optoelectronic device 1 of FIG. 1, from the structure such as described in relation with FIG. 7.

During this step, the future organic photodetector 30 is protected for subsequent operations. This protection is here performed by a portion 7460 of a fourth layer 746 made of positive or negative resist. Portion 7460 particularly covers first portion 7440 of third layer 744.

According to an embodiment, portion 7460 of fourth layer 746 is obtained by steps of photolithography on fourth layer 746, layer 746 then being deposited over the entire structure on the side of surface 700 of support 7, or by the deposition of a resin block directly on the first portion 7440 of third layer 744, for example, by inkjet printing, heliography, silk-screening, flexography, or nanoimprint.

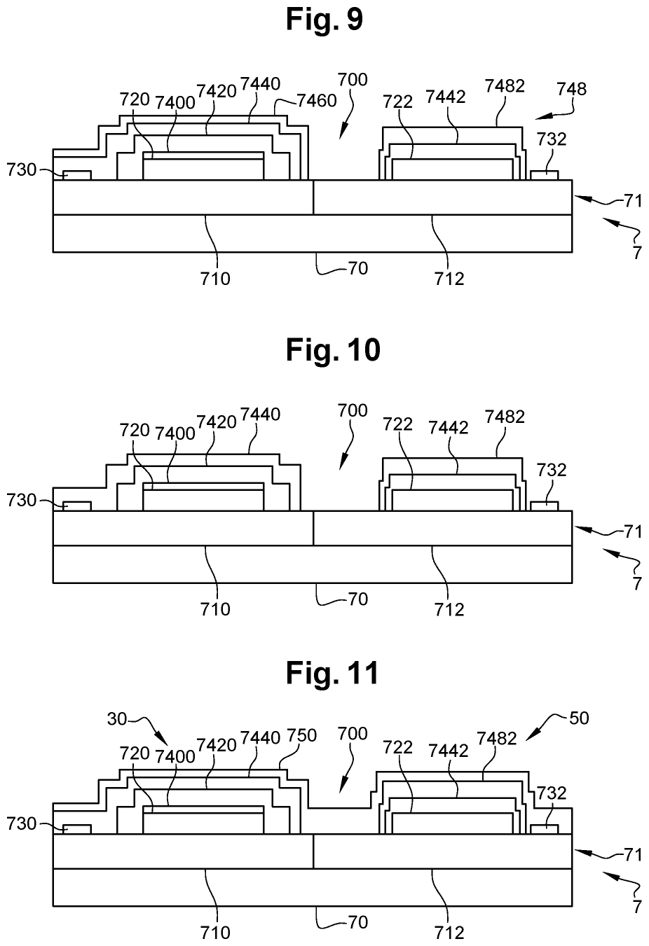

FIG. 9 is a partial simplified cross-section view of still another step of the implementation mode of the method of forming the optoelectronic device 1 of FIG. 1, from the structure such as described in relation with FIG. 8.

During this step, a portion 7482 of a fifth layer 748 is formed. Portion 7482 of fifth layer 748 covers the upper surface of second portion 7442 of third layer 744 (FIG. 6). In other words, portion 7482 of fifth layer 748 covers the second portion 7442 of third layer 744.

The method of forming portion 7482 of fifth layer 748 may correspond to a so-called additive process, for example, by direct printing of a fluid or viscous composition comprising the material forming portion 7482 of fifth layer 748 at the desired locations, for example, by inkjet printing, heliography, silk-screening, flexography, spray coating, or drop-casting, or nanoimprint.

The method of forming portion 7482 of fifth layer 748 may alternately correspond to a so-called subtractive process, where the material forming portion 7482 of fifth layer 748 is deposited all over the structure (“full plate” deposition) and where the non-used portions are then removed, for example, by photolithography.

In the case of a deposition over the entire structure and according to the material(s) used, fifth layer 748 may be deposited by liquid deposition. It may in particular be a method such as spin coating, spray coating, heliography, slot-die coating, blade coating, flexography, silk-screening, or dip coating. As a variant, fifth layer 748 may be deposited by cathode sputtering or by evaporation. According to the implemented deposition method, a step of drying the deposited material(s) may be provided.

Portion 7482 of fifth layer 748 forms an active layer 7482 of the future organic light-emitting component 50. Active layer 7482 corresponds to a region from which most of the electromagnetic radiation supplied by organic light-emitting component is emitted.

Fifth layer 748, and thus portion 7482 of fifth layer 748 is, preferably, made of a material selected from the group comprising:
for an organic light-emitting component 50 emitting green-colored light, that is, having a wavelength in a range from 510 nm to 570 nm, aluminum tris(8-hydroxyquinoleine) (III) (Alq₃) and a mixture made of poly(9,9-dihexyl fluorenyl-2,7-diyl) (PFO) and of poly(2-methoxy-5-(2-ethylhexyloxy)-1,4-phenylenevinylene) (MEH-PPV), portion 7482 of fifth layer 748 then having a thickness in the range from 20 nm to 120 nm;
for an organic light-emitting component 50 emitting blue-colored light, that is, having a wavelength in a range from 440 nm to 490 nm, 1,4-bis[2-(3-N-ethylcarbazoryl)-vinyl]benzene (BCzVB), portion 7482 of fifth layer 748 then having a thickness in the range from 10 nm to 100 nm;
for an organic light-emitting component 50 emitting red-colored light, that is, having a wavelength in a range from 600 nm to 720 nm, 4-(dicyanomethylene)-2-tert-butyl-6-(1,1,7,7-tetramethyljulolidine-4-yl-vinyl)-4H-pyrane (DCJTB), portion 7482 of fifth layer 748 then having a thickness in the range from 10 nm to 100 nm;
for an organic light-emitting component 50 emitting white-colored light, DCJTB doped with bis(2-methyl-8-quinolinato) (triphenylsiloxy) aluminum (III) (SAlq), portion 7482 of fifth layer 748 then having a thickness in the range from 30 nm to 150 nm; and
for an organic light-emitting component 50 emitting yellow-colored light, that is, having a wavelength in a range from 510 nm to 720 nm, the emitting material known under trade name “PDY-132” or “SuperYellow” sold by Merck, portion 7482 of fifth layer 748 then having a thickness in the range from 20 nm to 150 nm.

FIG. 10 is a partial simplified cross-section view of still another step of the implementation mode of the method of forming the optoelectronic device 1 of FIG. 1, from the structure such as described in relation with FIG. 9.

During this step, portion 7460 of fourth layer 746 is removed (and is thus not shown in FIG. 10) to expose first portion 7440 of third layer 744 (FIG. 6). The removal of portion 7460 of fourth layer 746 may be performed by any stripping method, for example, by dipping of the structure comprising portion 7460 of further layer 746 into a chemical bath.

FIG. 11 is a partial simplified cross-section view of still another step of the implementation mode of the method of forming the optoelectronic device 1 of FIG. 1, from the structure such as described in relation with FIG. 10.

During this step, a non-selective deposition (full-plate deposition) of a sixth layer 750 is performed on the side of the upper surface 700 of support 7. Sixth layer 750 thus covers:
free areas of upper surface 700 of support 7;
first portion 7440 of third layer 744 (and thus first connection pad 730);
portion 7482 of fifth layer 748 (and thus the second portion 7442 of third layer 744); and
second connection pad 732.

According to the material(s) used, the sixth layer 750 may be deposited by liquid deposition. It may in particular be a method such as spin coating, spray coating, heliography, slot-die coating, blade coating, flexography, silk-screening, or dip coating. As a variant, sixth layer 750 may be deposited by cathode sputtering or by evaporation. According to the implemented deposition method, a step of drying the deposited material(s) may be provided.

Sixth layer 750 is intended to form an electrode 750 common to photodetector 30 and to light-emitting component 50. Common electrode 750 forms a cathode electrode of the organic light-emitting component 50 and an anode electrode of organic photodetector 30. Common electrode 750 is located in a plane perpendicular to a light emission direction (52, FIG. 1) by light-emitting component 50 and/or to a light reception direction (32, FIG. 1) by photodetector 30.

First electrode 720 forms a cathode electrode 720 of organic photodetector 30. Second electrode 722 forms an anode electrode 722 of organic light-emitting component 50, different from the cathode electrode 720 of photodetector 30. In the shown example, the anode electrode 722 of organic light-emitting component 50 is electrically insulated from the cathode electrode 720 of organic photodetector 30.

In the shown example, light-emitting component 50 has a forward structure, while organic photodetector 30 has a reverse structure.

In operation, common electrode 750 is taken to a bias potential of photodetector 30 and of light-emitting component 50. This bias potential is for example applied to the first and second connection terminals 730, 732. The first connection terminal 730 being coupled, preferably connected, to second connection terminal 732, terminals 730, 732 then form both anode terminals of organic photodetector 30 and cathode terminals of organic light-emitting component 50.

According to an implementation mode, the common electrode formed by sixth layer 750 is connected to all the light-emitting components 50 and to all the photodetectors 30 forming part of a same row or of a same column of the pixel array 10 of the optoelectronic device 1 of FIG. 1.

Sixth layer 750 is at least partially transparent to the light radiation that it receives. Sixth layer 750 may be made of a transparent conductive material, for example, of transparent conductive oxide (TCO), of carbon nanotubes, of graphene, of a conductive polymer, of a metal, or of a mixture or an alloy of at least two of these compounds. Sixth layer 750 may have a monolayer or multilayer structure.

Examples of TCOs capable of forming sixth layer 750 are indium tin oxide (ITO), aluminum zinc oxide (AZO), and gallium zinc oxide (GZO), zinc tin oxide (ZTO), fluorine tin oxide (FTC)), titanium nitride (TiN), molybdenum oxide (MoO₃), vanadium pentoxide (V₂O₅), and tungsten oxide (WO₃).

An example of a conductive polymer capable of forming sixth layer 750 is the polymer known as PEDOT:PSS, which is a mixture of poly(3,4)-ethylenedioxythiophene and of sodium poly(styrene sulfonate), and polyaniline, also called PAni.

Examples of metals capable of forming sixth layer 750 are silver, aluminum, gold, copper, nickel, titanium, and chromium. Sixth layer 750 may be made of an alloy of magnesium and silver (MgAg). An example of a multilayer structure capable of forming sixth layer 750 is a multilayer AZO and silver structure of AZO/Ag/AZO type.

The thickness of sixth layer 750 may be in the range from 10 nm to 5 μm, for example, in the order of 60 nm. In the case where sixth layer 750 is metallic, the thickness of sixth layer 750 is smaller than or equal to 20 nm, preferably smaller than or equal to 10 nm.

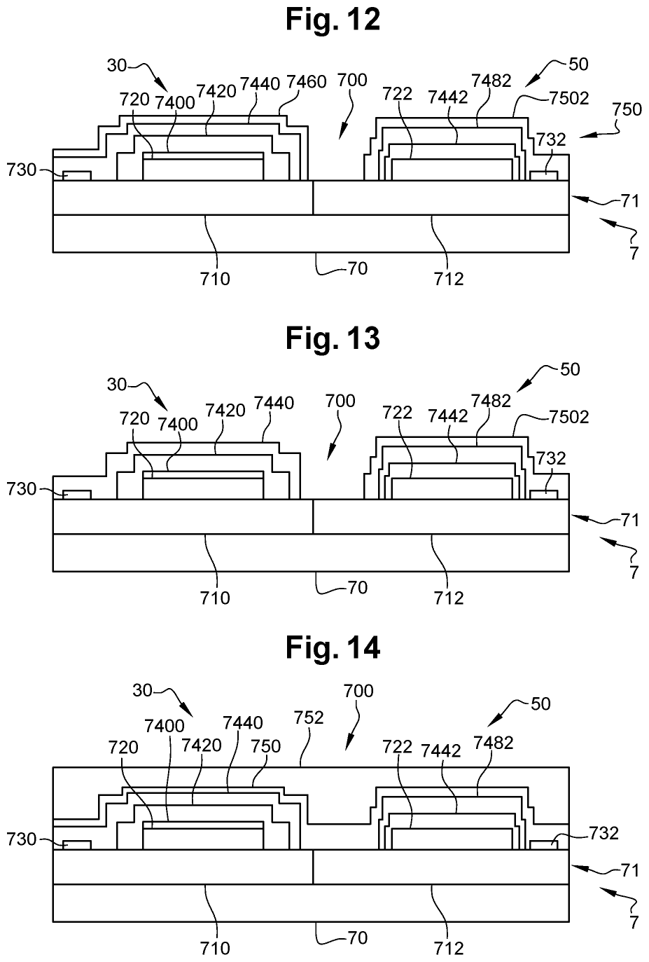

FIG. 12 is a partial simplified cross-section view of a step of a variant of the implementation mode of the method of forming the optoelectronic device 1 of FIG. 1, based on the structure such as described in relation with FIG. 9.

During this step, only a portion 7502 of sixth layer 750 is formed. Portion 7502 of sixth layer 750 covers portion 7482 of fifth layer 748 (and thus the second portion 7442 of third layer 744) and second connection pad 732.

The method of forming portion 7502 of sixth layer 750 may correspond to a so-called additive process, for example, by direct printing of a fluid or viscous composition comprising the material forming portion 7502 of sixth layer 750 at the desired location, for example, by inkjet printing, heliography, silk-screening, flexography, spray coating, drop-casting, or nanoimprint.

The method of forming portion 7502 of sixth layer 750 may alternately correspond to a so-called subtractive method, where sixth layer 750 is deposited over the entire structure (full-plate deposition) similarly to the step discussed in relation with FIG. 11, and where the portions which have not been used are then removed, for example, by photolithography. In the case where a photolithography technique is implemented, a resin similar to that forming portion 7460 of fourth layer 746 is preferably used (FIG. 7).

In the case of a deposition over the entire structure and according to the material(s) used, sixth layer 750 may be deposited by liquid deposition. It may in particular be a method such as spin coating, spray coating, heliography, slot-die coating, blade coating, flexography, silk-screening, or dip coating. As a variant, sixth layer 750 may be deposited by cathode sputtering or by evaporation. According to the implemented deposition method, a step of drying the deposited material(s) may be provided.

In practice, the first and second connection pads 730, 732 are interconnected. Portion 7502 of sixth layer 750 and first portion 7440 of third layer 744 thus form an electrode common to photodetector 30 and to organic light-emitting component 50.

Portion 7502 of sixth layer 750 is preferably made of a material similar to those discussed in relation with FIG. 11 for sixth layer 750.

FIG. 13 is a partial simplified cross-section view of another step of the alternative implementation mode of the method of forming the optoelectronic device 1 of FIG. 1, from the structure such as described in relation with FIG. 12.

During this step, portion 7460 of fourth layer 746 is removed (and thus not shown in FIG. 13) to expose the first portion 7440 of layer 744. The removal of portion 7460 of fourth layer 746 may be performed by any stripping method, for example, by dipping of the structure comprising portion 7460 of fourth layer 746 into a chemical bath. In the case where a photolithography operation is implemented at the step previously discussed in relation with FIG. 12 to form portion 7502 of sixth layer 750, the resin used for this photolithography operation is preferably removed at the same time as portion 7460 of fourth layer 746.

It is assumed hereafter that the variant discussed in relation with FIGS. 12 and 13 is not retained in the implementation mode of the described method. Transposing the implementation of the following steps based on the structure discussed in relation with FIG. 13 is however within the abilities of those skilled in the art based on the indications provided hereafter.

FIG. 14 is a partial simplified cross-section view of still another step of the implementation mode of the method of forming the optoelectronic device 1 of FIG. 1, from the structure such as described in relation with FIG. 11.

During this step, a non-selective deposition (full-plate deposition) of a seventh layer 752 is performed on the side of upper surface 700 of support 7. Seventh layer 752 thus integrally covers sixth layer 750, that is, the electrode common to photodetector 30 and to light-emitting component 50, previously deposited during the step discussed in relation with FIG. 11.

According to the material(s) used, seventh layer 752 may be deposited by liquid deposition. It may in particular be a method such as spin coating, spray coating, heliography, slot-die coating, blade coating, flexography, silk-screening, or dip coating. As a variant, seventh layer 752 may be deposited by cathode sputtering or by evaporation. According to the implemented deposition method, a step of drying the deposited material(s) may be provided.

Seventh layer 752 is intended to form a buffer layer (or intermediate layer). Seventh layer 752 is transparent or partially transparent to visible light. Seventh layer 752 is preferably substantially air- or water-tight.

According to this implementation mode, seventh layer 752 acts both:
as a so-called “planarization” layer, that is, as a layer enabling to obtain a structure having a planar upper surface; and
as a barrier layer, that is, as a layer enabling to avoid the degradation, due to an exposure to water or to the moisture contained, for example, in the ambient air, of the organic materials forming photodetector 30 and light-emitting component 50.

Seventh layer 752 may be made of a dielectric material based on one or a plurality of polymers. Seventh layer 752 may in particular be made of a polymer known under trade name “lisicon D320” sold by MERCK or of a polymer known under trade name “lisicon D350” sold by MERCK. The thickness of seventh layer 752 is then in the range from 0.2 μm to 5 μm.

Seventh layer 752 may be made of a fluorinated polymer, particularly the fluorinated polymer commercialized under trade name “Cytop” by Bellex, of polyvinylpyrrolidone (PVP), of polymethyl methacrylate (PMMA), of polystyrene (PS), of parylene, of polyimide (PI), of acrylonitrile butadiene styrene (ABS), of polydimethylsiloxane (PDMS), of a photolithography resin, of epoxy resin, of acrylate resin, or of a mixture of at least two of these compounds.

The material forming seventh layer 752 may in particular be selected from the group comprising a polyepoxide or a polyacrylate. Among polyepoxides, the material forming seventh layer 752 may be selected from the group comprising bisphenol A epoxy resins, particularly the diglycidylether of bisphenol A (DGEBA) and the diglycidylethers of bisphenol A and of tetrabromobisphenol A, bisphenol F epoxy resins, novolac epoxy resins, particularly epoxy-phenol-novolacs (EPN) and epoxy-cresol-novolacs (ECN), aliphatic epoxy resins, particularly epoxy resins with glycidil groups and cycloaliphatic epoxides, glycidyl amine epoxy resins, particularly the glycidyl ethers of methylene dianiline (TGMDA), and a mixture of at least two of these compounds. Among polyacrylates, the material forming seventh layer 752 may be made from monomers comprising acrylic acids, methylmethacrylate, acrylonitrile, methacrylates, methyl acrylate, ethyl acrylate, 2-chloroethyl vinyl ether, 2-ethylhexyl acrylate, hydroxyethyl methacrylate, butyl acrylate, butyl methacrylate, trimethylolpropane triacrylate (TMPTA), or derivatives of these products.

Seventh layer 752 may be formed of a silicon nitride multilayer structure (SiN) and of silicon oxide (SiO2). The seventh layer may be a silicon nitride or silicon oxide monolayer deposited by PECVD or by PVD.

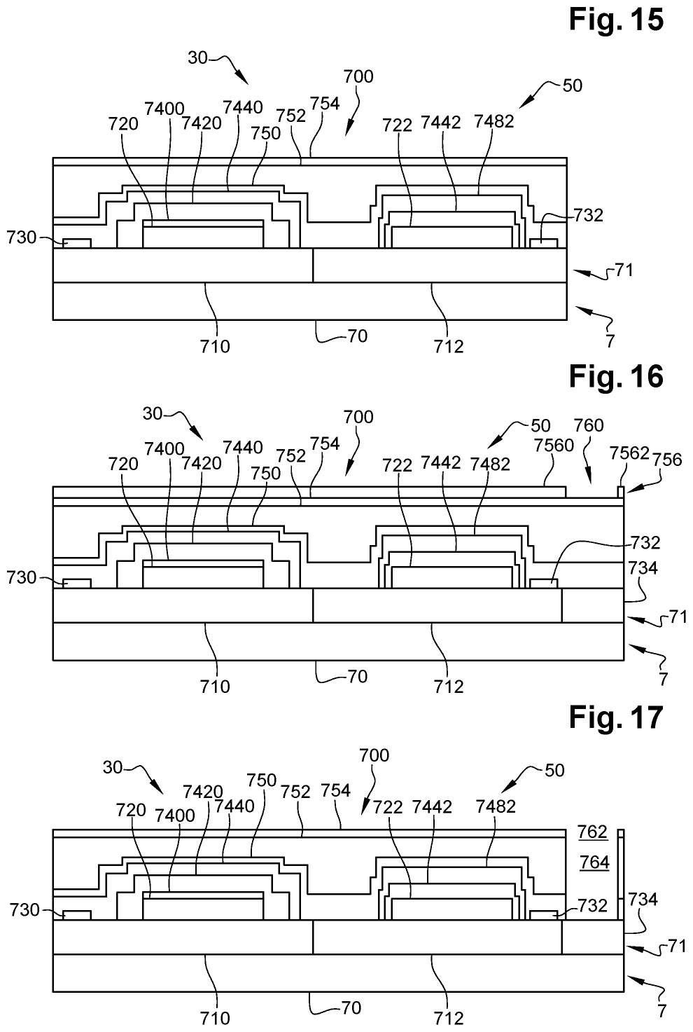

FIG. 15 is a partial simplified cross-section view of still another step of the implementation mode of the method of forming the optoelectronic device 1 of FIG. 1, from the structure such as described in relation with FIG. 14.

During this step, a non-selective deposition (full-plate deposition) of an eighth layer 754 is performed on the side of upper surface 700 of support 7. Eighth layer 754 thus integrally covers the previously-deposited seventh layer 752. Eighth layer 754 is intended to passivate the structure obtained at the previous step. In the rest of the disclosure, eighth layer 754 is also called passivation layer 754.

Eighth layer 754 may be made of alumina (Al₂O₃), of silicon nitride (Si₃N₄), or of silicon oxide (SiO₂). The thickness of passivation layer 754 is then in the range from 1 nm to 300 nm.

Eighth layer 754 may alternately be formed of a barrier substrate of a thickness capable of reaching 2 mm. According to an implementation mode, the barrier substrate is then coupled to a degassing material, also called getter material, enabling to absorb or to trap residual gases in the structure.

According to the material(s) used, eighth layer 754 may be deposited by atomic layer deposition (ALD), by physical vapor deposition (PVD) or by plasma-enhanced chemical vapor deposition (PECVD).

According to an implementation mode, eighth layer 754 receives an anti-reflective coating or treatment (not shown in FIG. 15). The anti-reflective coating particularly enables organic photodetector 30 to capture more light. The anti-reflective coating also decreases effects of biasing of the captured light.

FIG. 16 is a partial simplified cross-section view of still another step of the implementation mode of the method of forming the optoelectronic device 1 of FIG. 1, from the structure such as described in relation with FIG. 15.

During this step, the structure is protected for subsequent operations. The protection is here performed by a first portion 7560 and by a second portion 7562 of a ninth positive or negative resist layer 756. First and second portions 7560, 7562 partially cover eighth layer 754. More particularly, in FIG. 16, the first and second portions 7560, 7562 of ninth layer 756 are separated by a first opening 760. The first opening 760 crossing ninth layer 756 is located vertically in line with a third connection pad 734 formed in support 7. Third connection pad 734 is for example a pad of connection to a readout circuit associated with organic photodetector 30 or with a circuit for controlling organic light-emitting component 50.

According to an embodiment, the portions 7560 and 7562 of ninth layer 756 are obtained either by steps of photolithography on ninth layer 756, layer 756 then being deposited over the entire structure on the side of surface 700 of support 7, or by the deposition of separate resin blocks on the eighth portion 754, for example, by inkjet printing, heliography, silk-screening, flexography, or nanoimprint.

FIG. 17 is a partial simplified cross-section view of still another step of the implementation mode of the method of forming the optoelectronic device 1 of FIG. 1, from the structure such as described in relation with FIG. 16.

During this step, eighth layer 754 is etched to form a second opening 762 therein, vertically in line with third connection pad 734. Second opening 762 is formed in line with first opening 760 (not shown in FIG. 17). The etching of eighth layer 754 is preferably performed by chemical etching.

One then etches, still vertically in line with third connection pad 734, seventh layer 752 and sixth layer 750. As illustrated in FIG. 17, a third opening 764 is then formed. Opening 764 is formed in line with second opening 762. Third connection pad 734 is thus stripped to have its upper surface, that is, the surface of connection pad 734 located on the upper surface side 700 of support 7, exposed for subsequent connection operations (not detailed). The etching of seventh layer 752 and of sixth layer 750 is preferably performed by plasma etching.

The method described hereabove in relation with FIGS. 2 to 17 advantageously enables to form an optoelectronic device 1 (FIG. 1) comprising display screen 5, formed of an array of organic light-emitting components 50, and of image sensor 3, formed of an array of organic photodetectors 30. In a case where image sensor 3 is intended to acquire fingerprints, the method more particularly enables to form an optoelectronic device comprising a display screen integrating a fingerprint sensor. This thus enables to combine a plurality of functionalities, here, image display and the acquisition of biometric data, in a same screen. An electronic device, for example, a telephone, equipped with such a screen thus has an improved user-friendliness and dimensions smaller than that of a comparable telephone equipped with a conventional touch screen and with a separate fingerprint reader.

The presence of the common electrode formed, according to the retained implementation mode, either by sixth layer 750 or by portion 7502 of sixth layer 750 and the first portion 7440 of this layer 744 particularly enables to decrease the thickness of a portable electronic device integrating optoelectronic device 1.

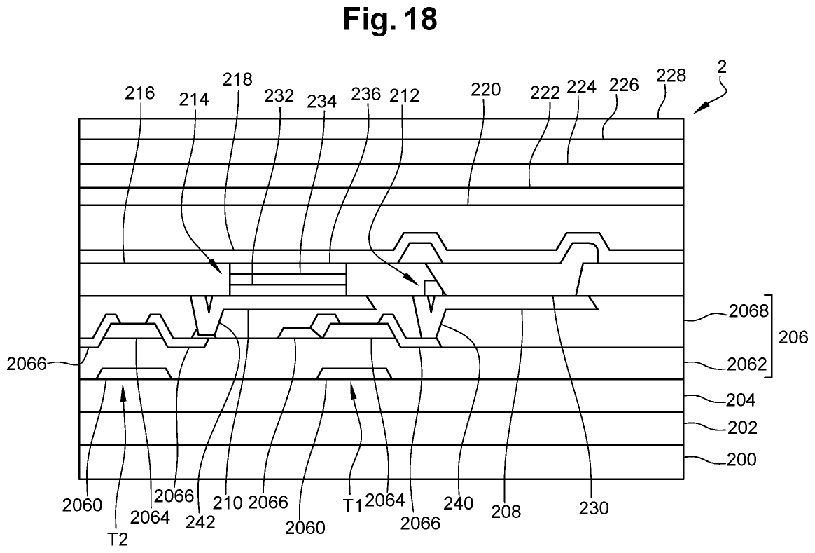

FIG. 18 is a partial simplified cross-section view of another embodiment of an optoelectronic device 2.

Device 2 comprises, from bottom to top in FIG. 18:
a lower encapsulation layer 200 for example made of polyethylene terephthalate (PET);
a flexible substrate 202 for example made of polyamide;
a buffer layer 204;
a stack 206 having thin-film transistors T1 and T2 formed therein;
electrodes 208, 210, each electrode 208 being coupled to one of transistors T1 and each electrode 210 being coupled to one of transistors T2;
light-emitting components 212, for example, organic light-emitting diodes 212, also called OLEDs, each light-emitting component 212 being in contact with one of electrodes 208, and photodetectors 214, for example, organic photodiodes 214, also called OPD, each photodetector 214 being in contact with one of electrodes 210, organic light-emitting diodes 212 and organic photodiodes 214 being laterally separated by an electrically-insulating layer 216;
a common upper electrode 218 interconnecting all the organic light-emitting photodiodes 212 and all the organic photodiodes 214;
an upper encapsulation layer 220;
a touch interface layer 222;
a bias layer 224;
an adhesive layer 226; and
a glass layer 228.

Preferably, the resolution of the optoelectronic device for light-emitting components 212 is in the order of 500 ppi and the resolution of the optoelectronic device for photodetectors 214 is in the order of 500 ppi. Preferably, the total thickness of optoelectronic device 2 is smaller than 2 mm.

According to this embodiment, each organic light-emitting diode 212 comprises an active region 230, electrodes 208 and 218 being in contact with active region 230.

According to this embodiment, each organic photodiode 214 comprises from bottom to top in FIG. 18:
a first interface layer 232 in contact with one of electrodes 210;
an active region 234 in contact with first interface layer 232; and
a second interface layer 236 in contact with active region 234, electrode 218 being in contact with second interface layer 236.

According to this embodiment, stack 206 comprises:
electrically-conductive tracks 2060 resting on barrier layer 204 and forming the gate conductors of transistors T1 and T2;
a layer 2062 of a dielectric material covering gate conductors 2060 and barrier layer 204 between gate conductors 2060 and forming the gate insulators of transistors T1 and T2;
active regions 2064 resting on dielectric layer 2062 opposite gate conductors 2060;
electrically-conductive tracks 2066 in contact with active regions 2064 and forming the drain and source contacts of transistors T1 and T2; and
a layer 2068 of a dielectric material, or insulating layer 2068, covering active regions 2064 and electrically-conductive tracks 2066, electrodes 208 resting on layer 2068 and being connected to some of conductive tracks 2066 by conductive vias 240 crossing insulating layer 2068 and electrodes 210 resting on layer 2068 and being connected to some of conductive tracks 2066 by conductive vias 242 crossing insulating layer 2068.

As a variant, transistors T1 and T2 may be of high gate type.

Interface layer 232 or 236 may correspond to an electron injection layer or to a hole injection layer. The work function of interface layer 232 or 236 is adapted to blocking, collecting, or injecting holes and/or electrons according to whether the interface layer plays the role of a cathode or of an anode. More particularly, when interface layer 232 or 236 plays the role of an anode, it corresponds to a hole injection and electron blocking layer. The work function of interface layer 232 or 236 is then greater than or equal to 4.5 eV, preferably greater than or equal to 5 eV. When interface layer 232 or 236 plays the role of a cathode, it corresponds to an electron injection and hole blocking layer. The work function of interface layer 232 or 236 is then smaller than or equal to 4.5 eV, preferably smaller than or equal to 4.2 eV.

According to an embodiment, electrode 208 or 218 advantageously directly plays the role of an electron injection layer or of a hole injection layer for light-emitting diode 212 and it is not necessary to provide, for light-emitting diode 212, an interface “sandwiching” active region 230 and playing the role of an electron injection layer or of a hole injection layer. According to another embodiment, interface layers playing the role of an electron injection layer or of a hole injection layer may be provided between active region 230 and electrodes 208 and 218.

The optoelectronic device 2 of FIG. 18 may advantageously be formed by adapting the method discussed in relation with FIGS. 2 to 17. Such an adaptation is within the abilities of those skilled in the art based on the functional indications provided hereabove.

According to an embodiment, optoelectronic device 2 comprises one or a plurality of elements (not shown) advantageously placed above organic photodiode 214 and enabling it to perform an angular selection of light rays reflected by a user's finger. These elements may for example take the form:
of a black layer provided with openings;
of lenses; or
of a black layer provided with openings having lenses aligned therewith.

Various embodiments, implementation modes, and variations have been described. Those skilled in the art will understand that certain features of these various embodiments, implementation modes, and variants may be combined, and other variants will occur to those skilled in the art.

Finally, the practical implementation of the described embodiments, implementation modes, and variations is within the abilities of those skilled in the art based on the functional indications given hereabove. In particular, other deposition and/or etching techniques may be implemented on forming of optoelectronic device 1 or 2, particularly according to the materials used.

1. A pixel comprising:
at least one organic light-emitting component comprising a first hole injection layer; and
at least one organic photodetector comprising a second hole injection layer,
wherein the first and second hole injection layers are made of a same material.

2. The pixel according to claim 1, wherein:
the first hole injection layer is coated with a first active layer of the organic light-emitting component; and
the second hole injection layer coats a second active layer of the organic photodetector.

3. The pixel according to claim 2, wherein the first active layer and the second hole injection layer are coated with a same electrode.

4. The pixel according to claim 3, wherein the electrode forms an anode electrode of the organic photodetector and a cathode electrode of the organic light-emitting component.

5. The pixel according to claim 1, wherein the material of the first and second hole injection layers is a mixture of poly(3,4)-ethylenedioxythiophene and of polystyrene sodium sulfonate, PEDOT:PSS.

6. The pixel according to claim 1, wherein the first and second hole injection layers are electrically insulated from each other.

7. The pixel according to claim 1, wherein the first and second hole injection layers are perpendicular to a direction of light emission by the organic light-emitting component and to a direction of light reception by the organic photodetector.

8. The pixel according to claim 1, wherein:
the organic light-emitting component further comprises an anode electrode; and
the organic photodetector further comprises a cathode electrode electrically insulated from the anode electrode of the organic light-emitting component.

9. A method of manufacturing a pixel comprising:
at least one organic light-emitting component comprising a first hole injection layer; and
at least one organic photodetector comprising a second hole injection layer,
wherein the first and second hole injection layers are made of a same material.

10. The method according to claim 9, wherein the first hole injection layer and the second hole injection layer are formed during a same step.

11. The method according to claim 10, wherein the first hole injection layer and the second hole injection layer are formed from a same third layer.

12. (canceled)

13. An optoelectronic device comprising an array of pixels according to claim 1.

14. (canceled)

15. The device according to claim 13, comprising, above the organic photodetectors, one or a plurality of elements capable of performing an angular selection of light rays reflected by a user's finger, these elements taking the form:
of a black layer provided with openings;
of lenses; or
of a black layer provided with openings having lenses aligned therewith.

16. An optoelectronic device comprising:
an array of pixels, each of the pixels comprising:
at least one organic light-emitting component comprising a first hole injection layer; and
at least one organic photodetector comprising a second hole injection layer,
wherein the first and second hole injection layers are made of a same material;
wherein the first hole injection layer is coated with a first active layer of the organic light-emitting component and the second hole injection layer coats a second active layer of the organic photodetector;
wherein the first active layer and the second hole injection layer are coated with a same electrode; and
wherein the electrode is connected to all the organic light-emitting components and to all the organic photodetectors of a same row of the array.
